(19) United States
(12) Patent Application Publication
(10) Pub. No.: US 2024/0147692 A1
(43) Pub. Date: May 2, 2024

(54) SEMICONDUCTOR MEMORY DEVICES AND METHOD OF MANUFACTURING THE SAME

(71) Applicant: Samsung Electronics Co., Ltd., Suwon-si (KR)

(72) Inventor: Seungmin Lee, Suwon-si (KR)

(21) Appl. No.: 18/496,211

(22) Filed: Oct. 27, 2023

(30) Foreign Application Priority Data
Oct. 28, 2022 (KR) 10-2022-0141766

(51) Int. Cl. H10B 12/00

(52) U.S. Cl. CPC H10B 12/20; H10B 12/01; H10B 12/50

(57) ABSTRACT

A semiconductor memory device of the present invention is capable of high performance and high integration, and has an effect of configuring a semiconductor die including a vertical volatile memory structure and a vertical nonvolatile memory structure on one peripheral circuit structure. A semiconductor memory device provided includes a semiconductor substrate, a back gate structure having a cylindrical shape and extending in a vertical direction on the semiconductor substrate and including a back gate electrode layer and a back gate insulating layer surrounding the back gate electrode layer, a plurality of semiconductor patterns, each having a ring-shaped horizontal section surrounding the back gate structure, and spaced apart from each other in the vertical direction, and first to third conductive lines surrounding one of the plurality of semiconductor patterns and spaced apart from each other in the vertical direction.

### CROSS-REFERENCE TO RELATED APPLICATION

This application is based on and claims priority under 35 U.S.C. § 119 to Korean Patent Application No. 10-2022-0141766, filed on Oct. 28, 2022, in the Korean Intellectual Property Office, the disclosure of which is incorporated by reference herein in its entirety.

### BACKGROUND

Aspects of the inventive concept relate to a semiconductor memory device and a method of manufacturing the same, and more particularly, to a capacitorless semiconductor memory device and a method of manufacturing the same.

As miniaturized, multifunctional, and high-performance electronic products are required, high-capacity semiconductor memory devices are required, and increased integration is required to provide high-capacity semiconductor memory devices. Accordingly, high-integration and high-capacity semiconductor memory devices are required. Among these semiconductor memory devices, Dynamic Random Access Memory (DRAM) generally includes a capacitor, but since it is difficult to reduce the size of the capacitor in order to perform a memory function, there is a limit to high integration.

### SUMMARY

Aspects of the inventive concept provide a capacitorless semiconductor memory device capable of high performance and high integration.

Aspects of the inventive concept provide a manufacturing method of a capacitorless semiconductor memory device capable of high performance and high integration.

Issues addressed by the technical spirit of the inventive concept are not limited to the above-mentioned issues, and other issues not mentioned will be clearly understood by those skilled in the art from the following description.

According to an aspect of the inventive concept, there is provided a semiconductor memory device including a semiconductor substrate, a back gate structure having a cylindrical shape and extending in a vertical direction on the semiconductor substrate and including a back gate electrode layer and a back gate insulating layer surrounding the back gate electrode layer, a plurality of semiconductor patterns, each having a ring-shaped horizontal section surrounding the back gate structure, and spaced apart from each other in the vertical direction, first to third conductive lines surrounding one of the plurality of semiconductor patterns and spaced apart from each other in the vertical direction, and a front gate insulating layer disposed to continuously surround between the semiconductor pattern and the second conductive line, on an upper surface of the second conductive line, and on a lower surface of the second conductive line, wherein a region of the semiconductor pattern facing the first and third conductive lines is doped with a first conductivity type impurity, wherein a region of the semiconductor patterns facing the second conductive line is doped with second-conductivity-type impurity of an opposite type to the first-conductivity-type impurity.

According to another aspect of the inventive concept, there is provided a semiconductor memory device including a semiconductor substrate having a cell region and a stepped extension region, a back gate structure having a cylindrical shape and extending in a vertical direction on the semiconductor substrate in the cell region and including a back gate electrode layer and a back gate insulating layer surrounding the back gate electrode layer, a plurality of semiconductor patterns, each having a ring-shaped horizontal section surrounding the back gate structure, and spaced apart from each other in the vertical direction, a source line, a word line, and a bit line, which surround the semiconductor pattern and spaced apart from each other in the vertical direction, a front gate insulating layer disposed continuously between the semiconductor pattern and the word line, on an upper surface of the word line, and on a lower surface of the word line, and a first interconnection line electrically connected to the back gate structure on an upper portion of the cell region, and a second interconnection line electrically connected to the source line, the word line, and the bit line on an upper portion of the extension region, wherein a region of the semiconductor patterns facing the source line and the bit line is doped with a first-conductivity-type impurity, wherein a region of the semiconductor patterns facing the word line is doped with a second-conductivity-type impurity of an opposite type to the first-conductivity-type impurity.

According to another aspect of the inventive concept, there is provided a semiconductor memory device including a semiconductor substrate, a peripheral circuit structure disposed on the semiconductor substrate, a volatile memory structure and a nonvolatile memory structure disposed on the peripheral circuit structure, wherein the volatile memory structure is a vertical dynamic random access memory (DRAM) and comprises: a back gate structure having a cylindrical shape and extending in a vertical direction on the semiconductor substrate and including a back gate electrode layer and a back gate insulating layer surrounding the back gate electrode layer, a plurality of semiconductor patterns, each having a ring-shaped horizontal section surrounding the back gate structure, and spaced apart from each other in the vertical direction, a source line, a word line, and a bit line, which horizontally surround the semiconductor pattern and spaced apart from each other in the vertical direction, and a front gate insulating layer disposed continuously between the semiconductor pattern and the word line, on an upper surface of the word line, and on a lower surface of the word line, wherein the nonvolatile memory structure is a vertical NAND.

### BRIEF DESCRIPTION OF THE DRAWINGS

Embodiments of the inventive concept will be more clearly understood from the following detailed description taken in conjunction with the accompanying drawings in which:

FIG. 1 is a perspective view illustrating a semiconductor memory device according to an embodiment;

FIG. 2 is a perspective view illustrating a cell region of FIG. 1;

FIG. 3 is a plan view illustrating the cell region of FIG. 1;

FIG. 4 is an enlarged perspective view of region IV of FIG. 2;

FIG. 5 is a flowchart illustrating a method of manufacturing a semiconductor memory device according to an embodiment;

FIGS. 6 to 14 are cross-sectional views illustrating a method of manufacturing a semiconductor memory device in sequence according to an embodiment of the inventive concept;

FIG. 15 is a conceptual diagram illustrating a semiconductor die including a semiconductor memory device according to an embodiment; and

FIG. 16 is a configuration diagram illustrating a system including a semiconductor memory device according to an embodiment.

### DETAILED DESCRIPTION OF THE EMBODIMENTS

Hereinafter, embodiments of the technical ideas of the inventive concept will be described in detail with reference to the accompanying drawings.

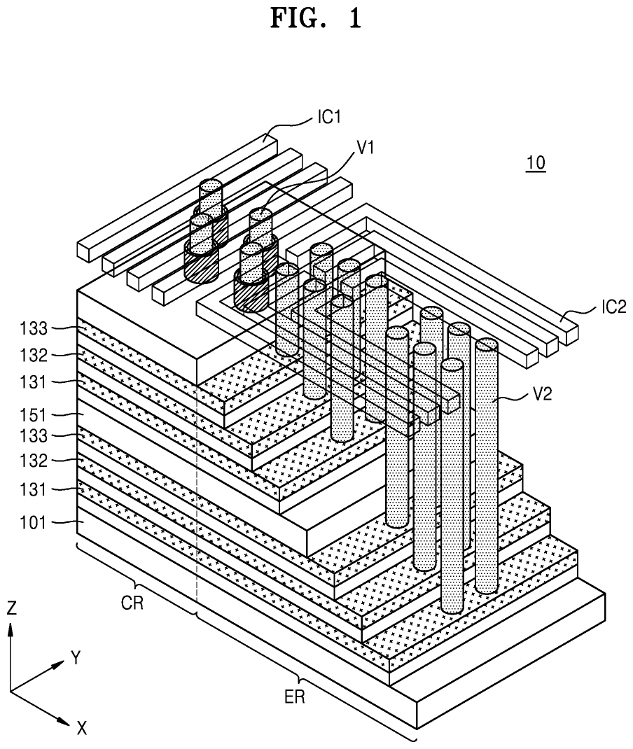

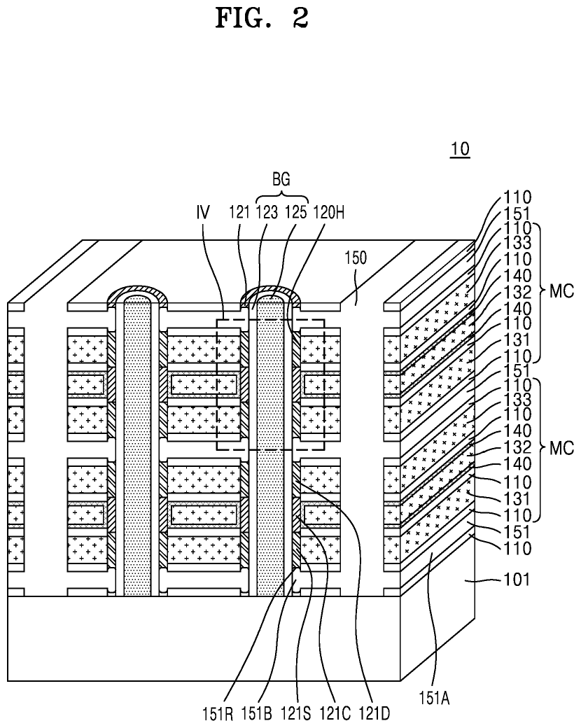

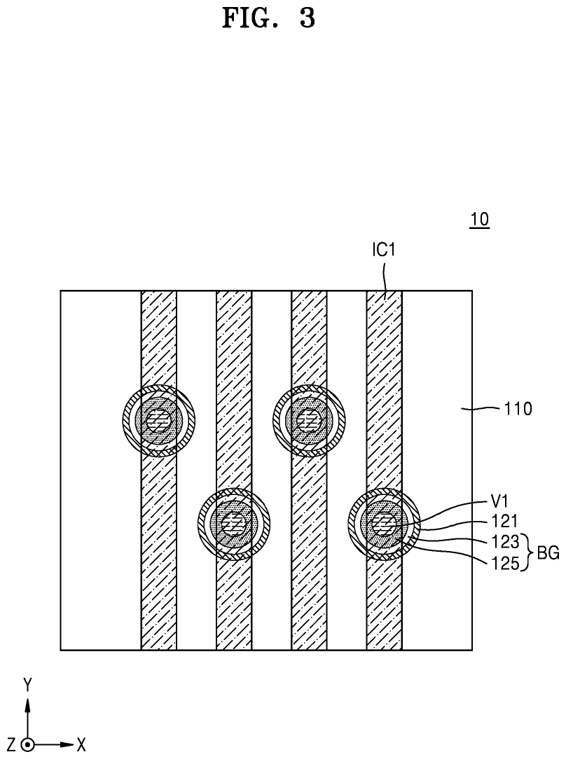

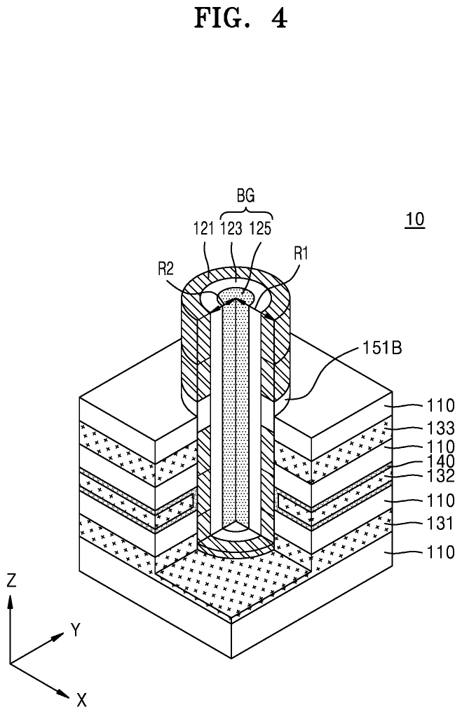

FIG. 1 is a perspective view showing a semiconductor memory device according to an embodiment of the technical ideas, FIG. 2 is a perspective view illustrating the cell region of FIG. 1, FIG. 3 is a plan view illustrating the cell region of FIG. 1, and FIG. 4 is an enlarged perspective view of area IV of FIG. 2.

For convenience of description, insides of some components (e.g., first and second interconnections) are shown transparently.

Referring to FIGS. 1 to 4 together, the semiconductor memory device 10 may include a memory cell MC array structure including a cell region CR and an extension region ER.

The cell region CR may be a region in which volatile type memory cells MC having a vertical structure are disposed while forming an array. The extension region ER may be a region in which connection parts for electrical connection between the memory cell MC array formed in the cell region CR and a peripheral circuit formed in a peripheral circuit region (not shown) are formed in a stepped shape.

The semiconductor substrate 101 may include or be formed of, for example, silicon (Si). Alternatively, the semiconductor substrate 101 may include or be formed of another semiconductor element, such as germanium (Ge), or a compound semiconductor, such as silicon carbide (SiC), gallium arsenide (GaAs), indium arsenide (InAs), and indium phosphide (InP). Alternatively, the semiconductor substrate 101 may have a silicon on insulator (SOI) structure. For example, the semiconductor substrate 101 may include a buried oxide (BOX) layer.

A plurality of line insulating layers 110 may be disposed on the semiconductor substrate 101 at regular intervals in a vertical direction (Z direction). The plurality of line insulating layers 110 may be formed of, for example, a material including at least one of silicon oxide, silicon nitride, and silicon oxynitride. Each of the plurality of line insulating layers 110 may be composed of a single layer made of one kind of insulating film, a double layer made of two kinds of insulating film, or a multi-layer made of a combination of at least three kinds of insulating films.

Each of the plurality of first to third conductive lines 131, 132, and 133 may be disposed on a corresponding one of the line insulating layers 110 at regular intervals in a vertical direction (Z direction). The plurality of first to third conductive lines 131, 132, and 133 may include or be formed of at least one of doped semiconductor materials (doped silicon, doped germanium, etc.), conductive metal nitrides (titanium nitride, tantalum nitride, etc.), a metal (tungsten, titanium, tantalum, etc.), and a metal-semiconductor compound (tungsten silicide, cobalt silicide, titanium silicide, etc.). A detailed description of the first to third conductive lines 131, 132, and 133 will be described later.

The plurality of back gate structures BG may be spaced apart from each other in a first horizontal direction (X direction) and a second horizontal direction (Y direction) on the semiconductor substrate 101 and may extend (e.g., lengthwise) in a vertical direction (Z direction). The plurality of back gate structures BG may be disposed in vertical openings penetrating the plurality of line insulating layers 110 and the plurality of first to third conductive lines 131, 132, and 133 in the cell region CR. In some embodiments, each of the plurality of back gate structures BG may have a circular pillar shape, e.g., a cylindrical pillar shape. In other embodiments, unlike shown in the drawing, each of the plurality of back gate structures BG may be tapered. For example, the width of each of the plurality of back gate structures BG in the horizontal direction (X and Y directions) may become smaller in a vertical direction approaching the semiconductor substrate 101.

The plurality of back gate structures BG may include a back gate insulating layer 123 disposed on an inner wall of the vertical opening and a back gate electrode layer 125 filling the inside of the vertical opening on the back gate insulating layer 123. In the drawings, the plurality of back gate structures BG are illustrated as having circular horizontal cross sections, but are not limited thereto.

The back gate insulating layer 123 may include or be formed of, for example, silicon oxide. In some embodiments, a back gate barrier layer (not shown) may be formed between the back gate insulating layer 123 and the back gate electrode layer 125. For example, each of the back gate electrode layer 125 and the back gate barrier layer (not shown) may include or be formed of at least one of a doped semiconductor material, a conductive metal nitride, a metal, and a metal-semiconductor compound.

The filling insulating layer 150 may pass through the plurality of line insulating layers 110 and the plurality of first to third conductive lines 131, 132, and 133. The filling insulating layer 150 may divide the memory cell MC array into unit blocks. For example, the semiconductor substrate 101 may be disposed on a lower surface of the filling insulating layer 150. For example, the filling insulating layer 150 may be formed on the semiconductor substrate. In some embodiments, the filling insulating layers 150 may be spaced apart from each other in a first horizontal direction (X direction) and extend along a second horizontal direction (Y direction). The filling insulating layer 150 may be disposed to be spaced apart from the plurality of back gate structures BG. The filling insulating layer 150 may be formed of, for example, silicon oxide, silicon nitride, or a combination thereof.

A plurality of semiconductor patterns 121 may be spaced apart from each other in a vertical direction (Z direction) on each sidewall of the plurality of back gate structures BG. The plurality of semiconductor patterns 121 may have a ring-shaped horizontal cross-section surrounding sidewalls of each back gate structure BG. In some embodiments, the radius R1 of the semiconductor pattern 121 may be greater than the radius R2 of the back gate structure BG. The semiconductor pattern 121 may be made of a doped semiconductor material. In some embodiments, the semiconductor pattern 121 may be formed of doped polysilicon.

The plurality of semiconductor patterns 121 and the plurality of channel isolation insulating layers 151 may be alternately disposed on sidewalls of the back gate structure BG. For example, the plurality of channel isolation insulating layers 151 may surround a sidewall portion of the back gate structure BG that is not covered by the semiconductor pattern 121. For example, each of the plurality of channel isolation insulation layers may contact the back gate insulating layer 123.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The first to third conductive lines 131, 132, and 133 may be positioned around one semiconductor pattern 121. The first to third conductive lines 131, 132, and 133 are adjacent to one end of one semiconductor pattern 121 and extend in a first horizontal direction (X direction), and may be spaced apart from each other in a vertical direction (Z direction). A line insulating layer 110 may be disposed between the first to third conductive lines 131, 132, and 133 adjacent in the vertical direction (Z direction), respectively. Each of the first to third conductive lines 131, 132, and 133 may be formed of any one of a doped semiconductor material, a conductive metal nitride, a metal, and a metal-semiconductor compound.

The plurality of first to third conductive lines 131, 132, and 133 include a plurality of first conductive lines 131, a plurality of second conductive lines 132, and a plurality of third conductive lines 133.

Regions of the plurality of semiconductor patterns 121 contacting the plurality of first conductive lines 131 may be source regions 121S. Each of the first conductive lines 131 may be a source line. Each source region 121S may include a semiconductor material doped with a high concentration of first conductivity type impurities. In some embodiments, the first conductivity type may be N-type, and for example, the source region 121S may be an N+ region heavily doped with N-type impurities.

A front gate insulating layer 140 may be disposed to surround the plurality of second conductive lines 132, and regions of the plurality of semiconductor patterns 121 facing the plurality of second conductive lines 132 may be channel regions 121C. Each of the second conductive lines 132 may be a front gate electrode layer or a word line. Each channel region 121C may include a semiconductor material doped with a low concentration of impurities of a second conductivity type opposite to that of the first conductivity type. Here, the second conductivity type may be P-type, and for example, the channel region 121C may be a P region lightly doped with P-type impurities.

Regions of the plurality of semiconductor patterns 121 contacting the plurality of third conductive lines 133 may be drain regions 121D. Each of the third conductive lines 133 may be a drain line or a bit line. Each drain region 121D may include a semiconductor material doped with first conductivity-type impurities at a high concentration. For example, the drain region 121D may be an N+ region heavily doped with N-type impurities.

For example, in the semiconductor memory device 10 of one embodiment, the source region 121S and the drain region 121D may be formed of the same conductivity type (e.g., N type), and the channel region 121C may be formed of a conductivity type (e.g., P type) opposite to that of the source region 121S and the drain region 121D, but the inventive concept is not limited thereto.

In this way, in the semiconductor memory device 10 of this embodiment, the semiconductor pattern 121 may operate as a channel and a source/drain of the memory cell MC. According to the electrical operation between the back gate including the back gate electrode layer 125 and the front gate including the word line, a plurality of carriers (e.g., holes) may be accumulated in a portion of the back gate insulating layer 123 adjacent to the channel region 121C.

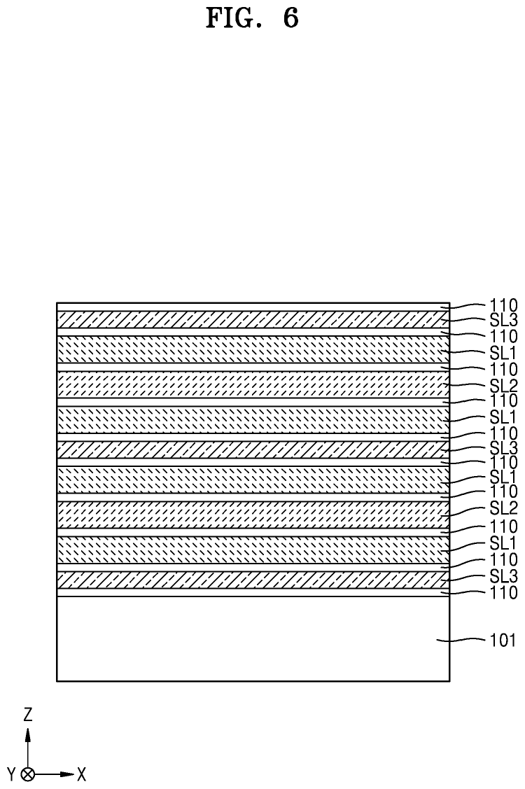

The semiconductor pattern 121 is sequentially composed of a source region 121S, a channel region 121C, and a drain region 121D in the vertical direction (Z direction), and the length along the vertical direction (Z direction) of each of the source region 121S, the channel region 121C, and the drain region 121D may be greater than the thickness along the vertical direction (Z direction) of each of the corresponding first to third conductive lines 131, 132, and 133. This is due to the replacement process of the first to third sacrificial layers SL1, SL2, and SL3 (see FIG. 6) to which the first to third conductive lines 131, 132, and 133 correspond.

A channel isolation insulating layer 151 may be disposed between adjacent semiconductor patterns 121 among the plurality of semiconductor patterns 121, e.g., in a vertical direction. The channel isolation insulating layer 151 includes a horizontal part 151A having a first thickness (e.g., in a vertical direction) and an edge part 151B having a second thickness (e.g., in the vertical direction) greater than the first thickness, and the plurality of semiconductor patterns 121 may be electrically separated/insulated from each other by the edge part 151B. The upper and lower surfaces of the edge part 151B of the channel isolation insulating layer 151 have a round shape 151R (e.g., in a cross-sectional view), which is due to a wet etching process. For example, the round shape 151R may be formed by a combination of an etchant of the wet etching process and the materials of the line insulating layer 110, the source region 121S, the drain region 121D, and/or the back gate insulating layer 123.

At the top of the cell region CR, a first via V1 is disposed at a point where the back gate structure BG and the first interconnection IC1 intersect, an upper surface of the first via V1 may contact the first interconnection IC1, and a lower surface of the first via V1 may be disposed to contact the back gate electrode layer 125. For example, the lower surface of the first via V1 may not contact the semiconductor pattern 121.

In the extension region ER, horizontal lengths of the first to third conductive lines 131, 132, and 133 constituting one memory cell MC may be different from each other. For example, the first conductive line 131 may be longer than the second conductive line 132, and the second conductive line 132 may be longer than the third conductive line 133. For example, in the extension region ER, the first to third conductive lines 131, 132, and 133 may have a stepped shape. First and second interconnections IC1 and IC2 of the present disclosure may be interconnection lines electrically connecting components of the semiconductor memory device of the present disclosure. For example, each of the interconnection lines IC1 and IC2 may be a conductor line formed of an electrically conductive material.

Accordingly, in the extension region ER, the vertical lengths of the second vias V2 connecting the first to third conductive lines 131, 132, and 133 constituting one memory cell MC to the second interconnection IC2 may be different from each other. For example, the second via V2 connected to the first conductive line 131 may be longer than the second via V2 connected to the second conductive line 132, and the second via V2 connected to the second conductive line 132 may be longer than the second via V2 connected to the third conductive line 133.

Also, in the semiconductor memory device 10, the first interconnection IC1 and the second interconnection IC2 may not be electrically connected to each other.

Accordingly, the semiconductor memory device 10 of one embodiment may operate in a manner of storing data in the memory cell MC by using the majority carriers accumulated in the back gate insulating layer 123. For example, the semiconductor memory device 10 may function as and/or may be a Dynamic Random Access Memory (DRAM) capable of performing read/write operations without using a separate capacitor structure. For example, each memory cell may store 1-bit data without using a capacitor as a memory cell. In this way, the capacitorless semiconductor memory device 10 may be implemented.

Since the semiconductor memory device 10 according to the technical ideas of the inventive concept may have high integration and high scalability, and may dramatically increase read/write operation speed to achieve high performance through the capacitorless vertical memory cell MC array structure, the semiconductor memory device 10 may have excellent competitiveness and high reliability.

As used herein, components described as being “electrically connected” are configured such that an electrical signal can be transferred from one component to the other (although such electrical signal may be attenuated in strength as it transferred and may be selectively transferred).

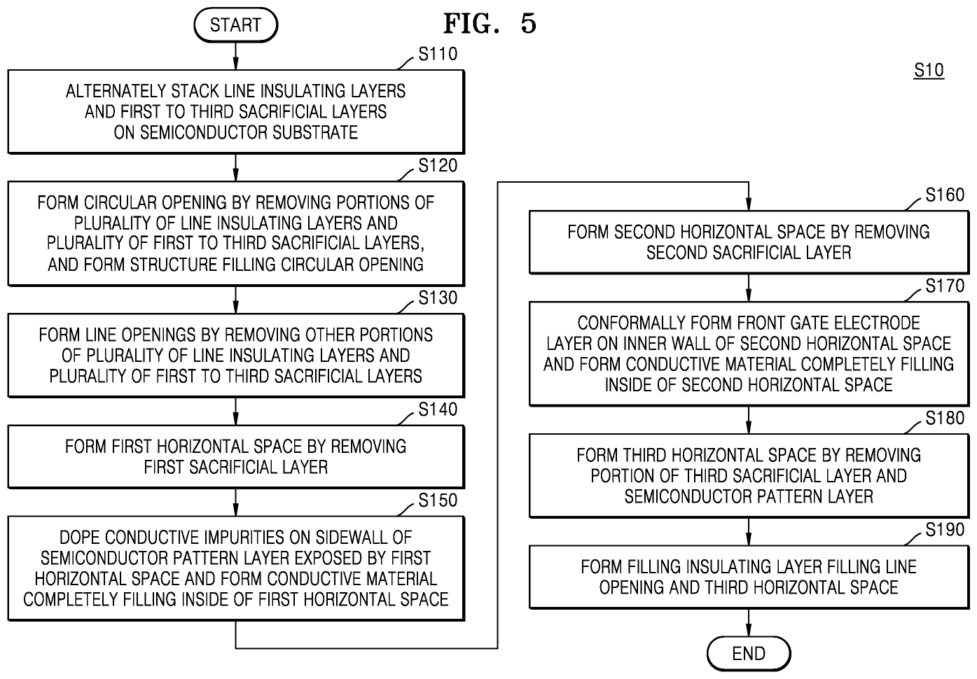

FIG. 5 is a flowchart illustrating a method of manufacturing a semiconductor memory device according to an embodiment.

Referring to FIG. 5, the method S10 of manufacturing a semiconductor memory device may include a process sequence of first to ninth operations S110 to S190.

When a certain embodiment may be implemented differently, a particular process order may be performed differently from the described order. For example, two processes described in succession may be performed substantially simultaneously, or may be performed in an order opposite to the described order.

The manufacturing method S10 of a semiconductor memory device according to an aspect of the technical ideas of the inventive concept may include a first operation S110 of alternately stacking line insulating layers and first to third sacrificial layers on a semiconductor substrate, a second operation S120 of forming a circular opening by removing portions of the plurality of line insulating layers and the plurality of first to third sacrificial layers, and forming a back gate structure filling the circular opening, a third operation S130 of forming line openings by removing other portions of the plurality of line insulating layers and the plurality of first to third sacrificial layers, a fourth operation S140 of forming a first horizontal space by removing the first sacrificial layer, a fifth operation S150 of doping conductive impurities on the sidewall of the semiconductor pattern layer exposed by the first horizontal space and forming a conductive material filling the first horizontal space, e.g., completely filling the first horizontal space, a sixth operation S160 of forming a second horizontal space by removing the second sacrificial layer, a seventh operation S170 of conformally forming a front gate electrode layer on the inner wall of the second horizontal space and forming a conductive material filling the inside of the second horizontal space, e.g., completely filling the inside of the second horizontal space, an eighth operation S180 of forming a third horizontal space by removing a portion of the third sacrificial layer and the semiconductor pattern layer, and a ninth operation S190 of forming a filling insulating layer filling the line openings and the third horizontal space.

The technical characteristics of each of the first to ninth operations S110 to S190 will be described in detail with reference to FIGS. 6 to 14 below.

FIGS. 6 to 14 are cross-sectional views illustrating a method of manufacturing a semiconductor memory device according to a process sequence according to an embodiment.

For convenience of description, description will be made focusing on the cell region CR (see FIG. 2) of the semiconductor memory device.

Referring to FIG. 6, the line insulating layers 110 and the first to third sacrificial layers SL1, SL2, and SL3 may be alternately stacked on the semiconductor substrate 101.

First, a line insulating layer (e.g., a first line insulating layer) 110 and a third sacrificial layer SL3 may be formed on the semiconductor substrate 101. Next, a line insulating layer (e.g., a second line insulating layer) 110 and a first sacrificial layer SL1 may be formed on the third sacrificial layer SL3. Next, a line insulating layer (e.g., a third line insulating layer) 110 and a second sacrificial layer SL2 may be formed on the first sacrificial layer SL1. Next, a line insulating layer (e.g., a fourth line insulating layer) 110 and a first sacrificial layer SL1 may be formed on the second sacrificial layer SL2. Such a layered structure may be sequentially and repeatedly provided.

The plurality of line insulating layers 110 and the plurality of first to third sacrificial layers SL1, SL2, and SL3 may be respectively formed by chemical vapor deposition (CVD), plasma enhanced CVD (PECVD), or atomic layer deposition (ALD) processes, but the inventive concept is not limited thereto.

In some embodiments, each of the plurality of line insulating layers 110 and the plurality of first to third sacrificial layers SL1, SL2, and SL3 may be formed of a material having an etching selectivity with respect to each other. For example, the plurality of line insulating layers 110 may be formed using silicon oxide, and each of the plurality of first to third sacrificial layers SL1, SL2, and SL3 may be formed using a different silicon-based material. Each of the plurality of line insulating layers 110 and the plurality of first to third sacrificial layers SL1, SL2, and SL3 may have a thickness of about several tens of nanometers (nm), but the inventive concept is not limited thereto.

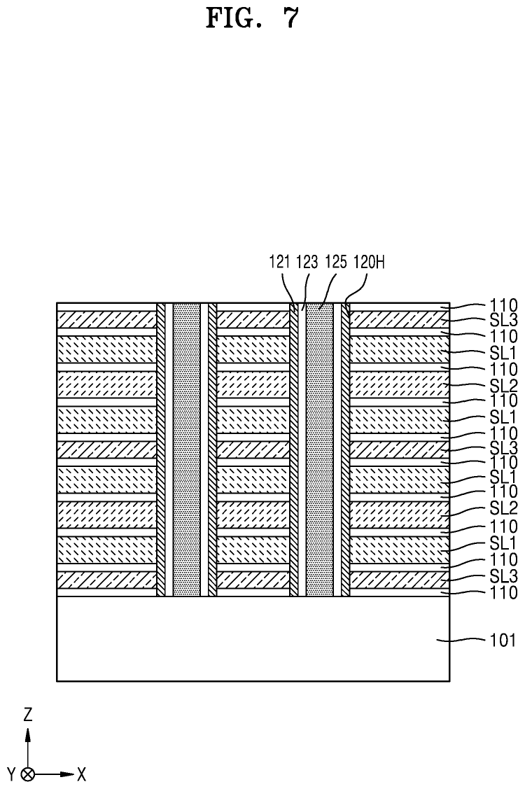

Referring to FIG. 7, a mask pattern (not shown) is formed on the uppermost line insulating layer 110, and the mask pattern is used as an etching mask so that circular openings 120H penetrating the plurality of line insulating layers 110 and the plurality of first to third sacrificial layers SL1, SL2, and SL3 may be formed.

The circular opening 120H may expose an upper surface of the semiconductor substrate 101. In some embodiments, the circular openings 120H may be spaced apart from each other in horizontal directions (X and Y directions) and extend (e.g., lengthwise) in a vertical direction (Z direction).

Each circular opening 120H is illustrated as having the same horizontal width throughout its entire height, but may have a tapered shape in which the horizontal width reduces approaching the semiconductor substrate 101. Each circular opening 120H is illustrated as having a circular horizontal cross section (see FIG. 3), but is not limited thereto.

First, the semiconductor pattern 121 may be formed on the inner wall of the circular opening 120H. The semiconductor pattern 121 may be formed using at least one of a thermal oxidation process, CVD, PECVD, or ALD process. The semiconductor pattern 121 may be formed to cover both inner walls of the plurality of line insulating layers 110 and inner walls of the plurality of first to third sacrificial layers SL1, SL2, and SL3. In some embodiments, the semiconductor pattern 121 may be formed of polysilicon lightly doped with P-type impurities.

Next, a back gate insulating layer 123 may be formed on an inner wall of the semiconductor pattern 121. The back gate insulating layer 123 may be formed using at least one of a thermal oxidation process, CVD, PECVD, or ALD process. In some embodiments, the back gate insulating layer 123 may be formed of silicon oxide.

Next, the back gate electrode layer 125 may be formed to fill the rest of the circular opening 120H. In some embodiments, the back gate electrode layer 125 may be formed of a metal or a metal compound.

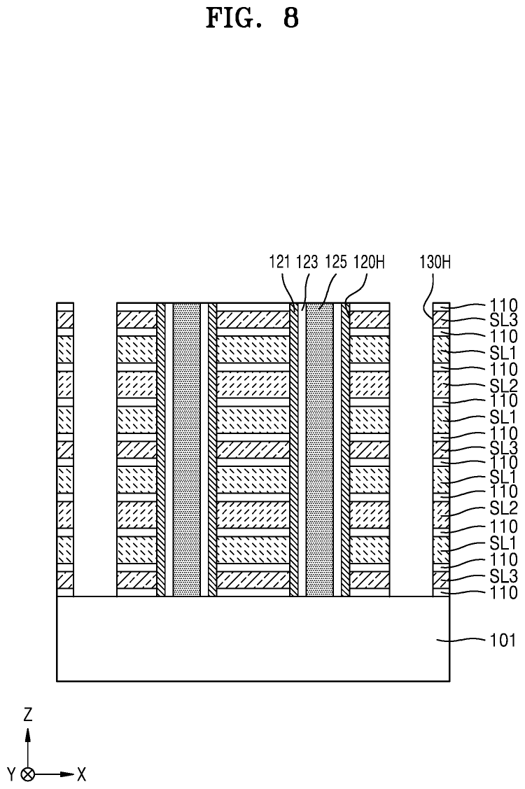

Referring to FIG. 8, a mask pattern (not shown) is formed on the uppermost line insulating layer 110, and the mask pattern is used as an etching mask so that the line openings 130H may be formed by removing portions of the plurality of line insulating layers 110 and the plurality of first to third sacrificial layers SL1, SL2, and SL3.

Each line opening 130H may expose an upper surface of the semiconductor substrate 101. The line openings 130H may be formed to be spaced apart from the circular openings 120H in the first horizontal direction (X direction). In some embodiments, the line openings 130H may be spaced apart from each other in/along a first horizontal direction (X direction) and may extend along a second horizontal direction (Y direction).

In FIG. 8, each line opening 130H is illustrated as having the same horizontal width throughout its entire height, but may have a tapered shape in which the horizontal width decreases in a direction approaching the semiconductor substrate 101.

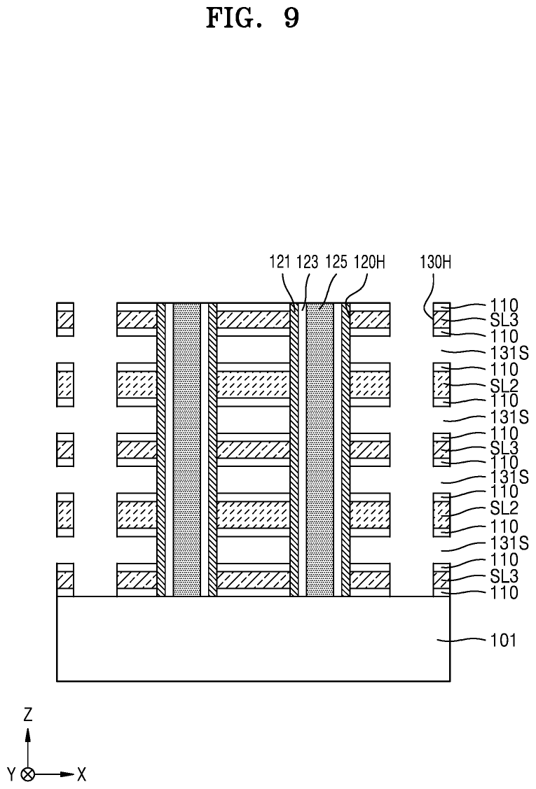

Referring to FIG. 9, a plurality of first horizontal spaces 131S communicating with and connected to the line opening 130H may be formed by removing the first sacrificial layer SL1, e.g., by removing all of the first sacrificial layer SL1 (see FIG. 8) exposed through the line opening 130H.

Since the first horizontal spaces 131S are formed by removing the first sacrificial layers SL1 (see FIG. 8) exposed through the line opening 130H, a thickness occupied by the first horizontal space 131S may be substantially the same as that of the first sacrificial layer SL1 (see FIG. 8).

Spatially relative terms, such as “beneath,” “below,” “lower,” “above,” “upper,” “downward,” “upward” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

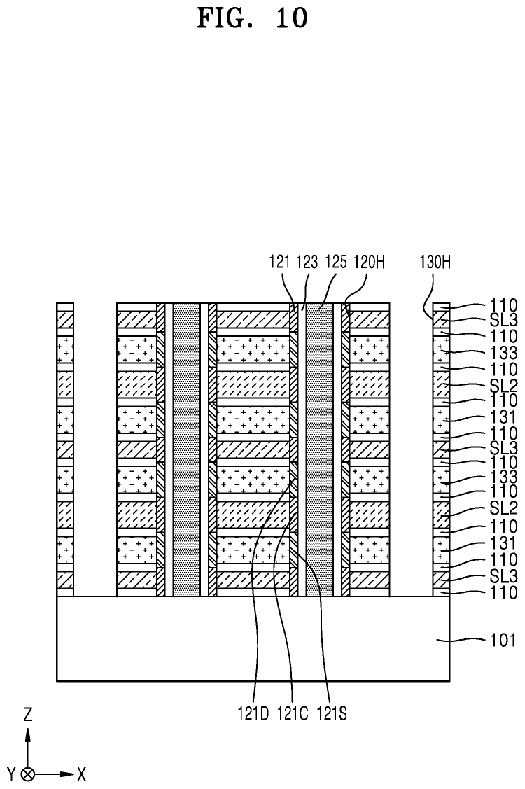

Referring to FIG. 10, a portion of the sidewall of the semiconductor pattern 121 exposed by the first horizontal space 131S (see FIG. 9) is heavily doped with first conductivity type impurities to form a source region 121S and a drain region 121D.

Here, the first conductivity type may be N-type, and for example, the source region 121S and the drain region 121D may be N+regions heavily doped with N-type impurities. In some embodiments, the doping process of the first conductivity type impurity may be performed by a vapor phase doping process or a plasma doping process.

Accordingly, a channel region 121C may be formed between the source region 121S and the drain region 121D. The channel region 121C may be a region doped with second conductivity type impurities at a low concentration. Here, the second conductivity type may be P-type, and for example, the channel region 121C may be a P region lightly doped with P-type impurities. As described above, the doping process of the second conductivity type impurity may be performed together during the formation of the semiconductor pattern 121.

Next, a conductive material may be formed to fill the first horizontal space 131S, e.g., to completely fill the first horizontal space 131S (see FIG. 9). The conductive material may be formed of a metal (e.g., tungsten) or a metal compound.

In some embodiments, a conductive material facing the source region 121S may be a first conductive line 131 or a source line, and a conductive material facing the drain region 121D may be a third conductive line 133, a drain line, or a bit line.

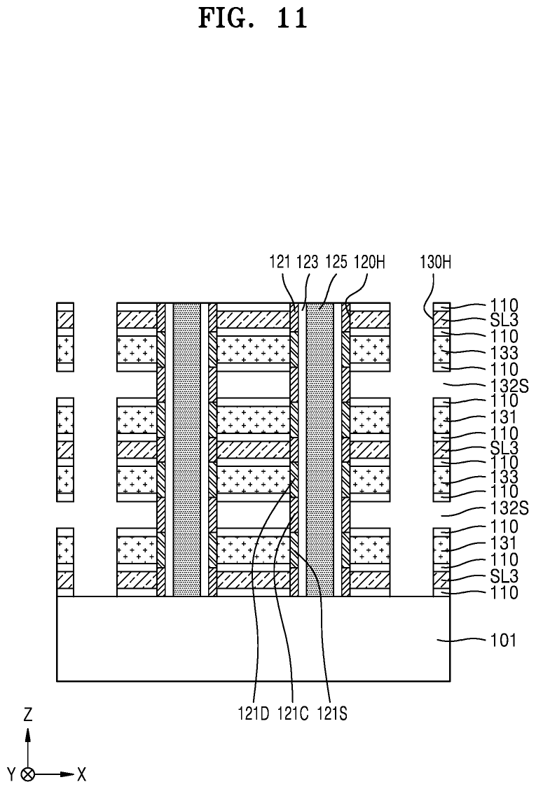

Referring to FIG. 11, a plurality of second horizontal spaces 132S connected to and communicating with the line opening 130H may be formed by removing the second sacrificial layer SL2, e.g., by removing all of the second sacrificial layer SL2 (see FIG. 10) exposed through the line opening 130H.

Since the second horizontal space 132S is formed by removing the second sacrificial layer SL2 (see FIG. 10) exposed through the line opening 130H, a thickness occupied by the second horizontal space 132S may be substantially the same as that of the second sacrificial layer SL2 (see FIG. 10).

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

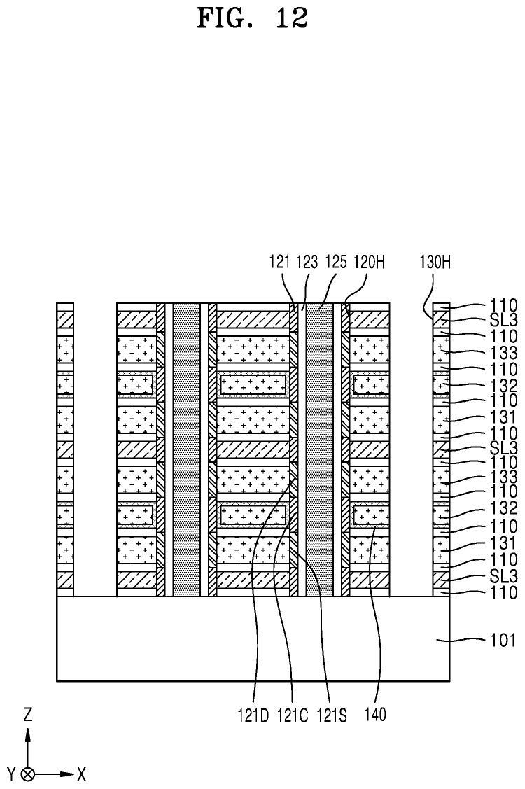

Referring to FIG. 12, the front gate insulating layer 140 is conformally formed on the inner wall of the second horizontal space 132S (see FIG. 9), and a conductive material may be formed fill the remaining interior of the second horizontal space 132S, e.g., to completely fill the remaining interior of the second horizontal space 132S (see FIG. 9).

The front gate insulating layer 140 may be formed of silicon oxide. The front gate insulating layer 140 may be conformally formed along an inner wall of the second horizontal space 132S (see FIG. 9).

The conductive material may be formed of a metal (e.g., tungsten) or a metal compound. In some embodiments, a conductive material facing the channel region 121C may be a second conductive line 132, a front gate electrode layer, or a word line.

Through this process, the plurality of front gate electrode layers may be formed to be spaced apart from each other in the vertical direction (Z direction) so that the plurality of front gate electrode layers correspond to one back gate electrode layer 125.

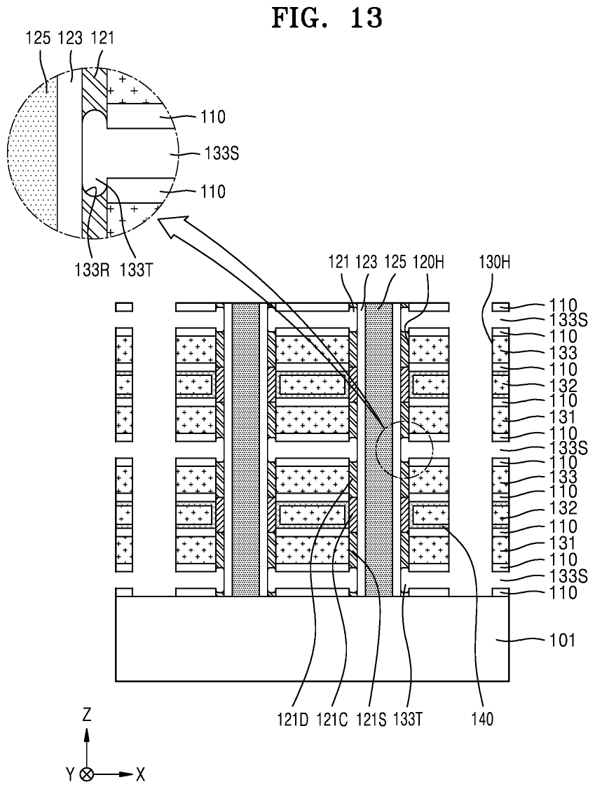

Referring to FIG. 13, a plurality of third horizontal spaces 133S connected to and communicating with the line opening 130H may be formed by removing the third sacrificial layer SL3, e.g., by removing all of the third sacrificial layer SL3 (see FIG. 12) exposed through the line opening 130H.

Since the third horizontal space 133S is formed by removing the third sacrificial layer SL3 (see FIG. 12) exposed through the line opening 130H, a thickness occupied by the third horizontal space 133S may be substantially the same as that of the third sacrificial layer SL3 (see FIG. 12).

In addition, a third vertical space 133T connected to and communicating with the third horizontal space 133S may be formed by removing a portion of the semiconductor pattern 121 exposed through the third horizontal space 1335.

Upper and lower portions of the third vertical space 133T may have a round shape 133R, e.g., in a cross-sectional view. This may be due to a wet etching process used to form the third vertical space 133T. For example, the round shape 133R may be formed by a combination of an etchant of the wet etching process and the materials of the line insulating layer 110, the semiconductor pattern 121, and/or the back gate insulating layer 123.

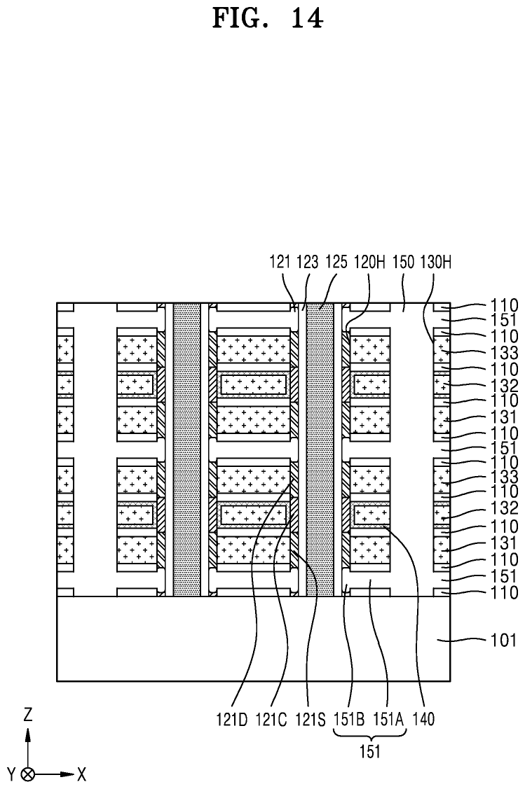

Referring to FIG. 14, a filling insulating layer 150 may be formed to fill the line opening 130H, the third horizontal space 133S, and the third vertical space 133T.

The filling insulating layer 150 may be formed of, for example, silicon oxide, silicon nitride, or a combination thereof. Here, the filling insulating layer 150 filling the third horizontal space 1335 and the third vertical space 133T may be a channel isolation layer 151.

For example, the channel isolation insulating layer 151 may include a horizontal part 151A filling the third horizontal space 133S, and an edge part 151B filling the third vertical space 133T.

Referring back to FIGS. 1 and 2, the semiconductor memory device 10 according to the technical ideas of the inventive concept is completed by forming the first interconnection IC1 at the top of the plurality of memory cells MC formed as described above.

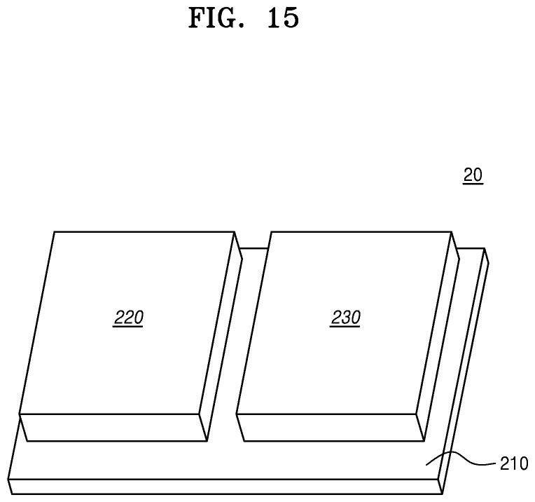

FIG. 15 is a conceptual diagram illustrating a semiconductor die 20 including a semiconductor memory device according to an embodiment.

Referring to FIG. 15, the semiconductor die 20 may include a volatile memory structure 220 and a nonvolatile memory structure 230 on one peripheral circuit region 210. The volatile memory structure 220 and the nonvolatile memory structure 230 may be embedded in a substrate including the peripheral circuit region 210, or may be mounted on the substrate as a form of semiconductor chips (e.g., a volatile memory chip 220 and a non-volatile memory chip 230).

Circuit elements necessary for driving memory devices included in the volatile memory structure 220 and the nonvolatile memory structure 230 may be disposed in the peripheral circuit region 210. The circuit element may be, for example, a read circuit or a write circuit, but is not limited thereto.

In the volatile memory structure 220, a semiconductor memory device 10 (see FIG. 1) according to the technical ideas of the inventive concept may be disposed. For example, the volatile memory structure 220 may be a vertical capacitorless DRAM.

The nonvolatile memory structure 230 may include a vertical memory cell having a structure the same as or similar to that of the semiconductor memory device 10 (see FIG. 1) according to an embodiment or the technical ideas of the inventive concept. For example, the nonvolatile memory structure 230 may be a vertical NAND flash memory.

Therefore, according to an embodiment or the technical ideas of the inventive concept, by forming the volatile memory structure 220 and the nonvolatile memory structure 230 having similar structures to each other in one peripheral circuit region 210, the memory hierarchy may be reduced, allowing for high speed, while some of the manufacturing processes are the same so that a hybrid memory that may be produced at a low cost may be manufactured.

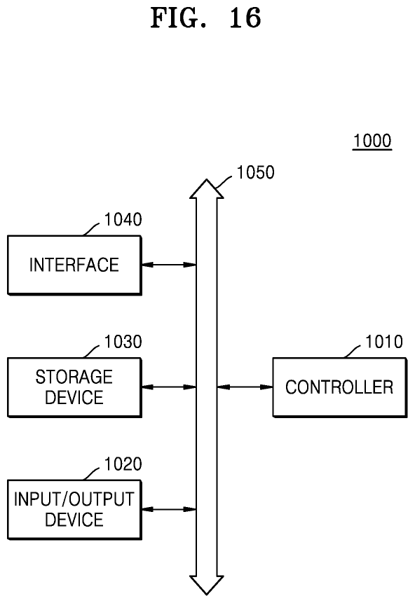

FIG. 16 is a configuration diagram illustrating a system including a semiconductor memory device according to an embodiment.

Referring to FIG. 16, the system 1000 includes a controller 1010, an input/output device 1020, a storage device 1030, an interface 1040, and a bus 1050.

The system 1000 may be a mobile system or a system that transmits or receives information. In some embodiments, the mobile system may be a portable computer, web tablet, mobile phone, digital music player, or memory card.

The controller 1010 is for controlling an executable program in the system 1000, and may include a microprocessor, a digital signal processor, a microcontroller, or a similar device.

The input/output device 1020 may be used to input data to or output data from the system 1000. The system 1000 may be electrically connected to an external device, for example, a personal computer or a network, using the input/output device 1020, and may exchange data with the external device. The input/output device 1020 may be, for example, a touch screen, a touch pad, a keyboard, and/or a display.

The storage device 1030 may store data for the operation of the controller 1010 or store data processed by the controller 1010. The storage device 1030 may include the semiconductor memory device 10 according to embodiments of the technical ideas of the inventive concept described above.

The interface 1040 may be a data transmission path between the system 1000 and an external device. The controller 1010, the input/output device 1020, the storage device 1030, and the interface 1040 may communicate with each other via the bus 1050.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

While aspects of the inventive concept have been particularly shown and described with reference to embodiments thereof, it will be understood that various changes in form and details may be made therein without departing from the spirit and scope of the following claims.

What is claimed is:

1. A semiconductor memory device comprising:
a semiconductor substrate;
a back gate structure having a cylindrical shape and extending in a vertical direction on the semiconductor substrate and including a back gate electrode layer and a back gate insulating layer surrounding the back gate electrode layer;
a plurality of semiconductor patterns, each having a ring-shaped horizontal section surrounding the back gate structure, and spaced apart from each other in the vertical direction;
first to third conductive lines surrounding one of the plurality of semiconductor patterns and spaced apart from each other in the vertical direction; and
a front gate insulating layer disposed to continuously surround between the semiconductor pattern and the second conductive line, on an upper surface of the second conductive line, and on a lower surface of the second conductive line,
wherein a region of the semiconductor patterns facing the first and third conductive lines is doped with a first-conductivity-type impurity,
wherein a region of the semiconductor patterns facing the second conductive line is doped with second-conductivity-type impurity of an opposite type to the first-conductivity-type impurity.

2. The semiconductor memory device of claim 1, wherein the semiconductor patterns are each composed of a source region, a channel region, and a drain region, arranged in sequence in the vertical direction,
wherein the source region faces the first conductive line and is doped with an N-type impurity,
wherein the channel region faces the second conductive line and is doped with a P-type impurity,
wherein the drain region faces the third conductive line and is doped with an N-type impurity.

3. The semiconductor memory device of claim 2, wherein a length of each of the source region, the channel region, and the drain region along the vertical direction is greater than a thickness of each of the corresponding first to third conductive lines.

4. The semiconductor memory device of claim 1, further comprising a channel isolation insulating layer disposed between adjacent semiconductor patterns among the plurality of semiconductor patterns,
wherein the channel isolation insulating layer comprises a horizontal part having a first thickness and an edge part having a second thickness greater than the first thickness,
wherein the plurality of semiconductor patterns are electrically separated from each other by the edge part of the channel isolation insulating layer.

5. The semiconductor memory device of claim 4, wherein upper and lower surfaces of the edge part of the channel isolation insulating layer have a round shape.

6. The semiconductor memory device of claim 1, further comprising a plurality of line insulating layers disposed between the first to third conductive lines, below the first conductive line, and above the third conductive line.

7. The semiconductor memory device of claim 6, wherein a sidewall of each of the first and third conductive lines is in contact with the semiconductor pattern,
wherein a sidewall of the second conductive line is in contact with the front gate insulating layer.

8. The semiconductor memory device of claim 1, wherein a plurality of the second conductive lines are disposed to face one back gate structure,
wherein the semiconductor memory device is configured such that holes are accumulated for a preset time in a region of the back gate insulating layer facing the second conductive lines.

9. The semiconductor memory device of claim 1, wherein a line-shaped first interconnection line is disposed on the back gate structure,
wherein a first via is disposed at a point where the back gate structure and the first interconnection line overlap.

10. The semiconductor memory device of claim 9, wherein an upper surface of the first via is in contact with the first interconnection line,
wherein a lower surface of the first via is in contact with the back gate electrode layer.

11. A semiconductor memory device comprising:
a semiconductor substrate having a cell region and a stepped extension region;
a back gate structure having a cylindrical shape and extending in a vertical direction on the semiconductor substrate, in the cell region, and including a back gate electrode layer and a back gate insulating layer surrounding the back gate electrode layer;
a plurality of semiconductor patterns, each having a ring-shaped horizontal section surrounding the back gate structure, and spaced apart from each other in the vertical direction;
a source line, a word line, and a bit line, which surround the semiconductor pattern and spaced apart from each other in the vertical direction;
a front gate insulating layer disposed continuously between the semiconductor pattern and the word line, on an upper surface of the word line, and on a lower surface of the word line; and
a first interconnection line electrically connected to the back gate structure, on an upper portion of the cell region; and
a second interconnection line electrically connected to the source line, the word line, and the bit line, on an upper portion of the extension region,
wherein a region of the semiconductor patterns facing the source line and the bit line is doped with a first-conductivity-type impurity,
wherein a region of the semiconductor patterns facing the word line is doped with a second-conductivity-type impurity of an opposite type to the first-conductivity-type impurity.

12. The semiconductor memory device of claim 11, wherein each of the semiconductor patterns comprises a source region, a channel region, and a drain region, sequentially arranged in the vertical direction,
wherein the source region faces the source line, and a thickness of the source region in the vertical direction is greater than a thickness of the source line in the vertical direction,
wherein the channel region faces the word line, and a thickness of the channel region in the vertical direction is greater than a thickness of the word line in the vertical direction,
wherein the drain region faces the bit line, and a thickness of the drain region in the vertical direction is greater than a thickness of the bit line in the vertical direction.

13. The semiconductor memory device of claim 11, further comprising a channel isolation insulating layer including: a horizontal part having a first thickness in the vertical direction; and an edge part having a second thickness in the vertical direction greater than the first thickness,
wherein the plurality of semiconductor patterns are separated apart from each other in the vertical direction by the edge part of the channel isolation insulating layer.

14. The semiconductor memory device of claim 11, wherein, in the cell region, a first via is disposed at a point where the back gate structure and the first interconnection line vertically overlap,
wherein an upper surface of the first via is in contact with the first interconnection line,
wherein a lower surface of the first via is in contact with the back gate electrode layer.

15. The semiconductor memory device of claim 11, wherein, in the extension region, a horizontal length of the source line is longer than a horizontal length of the word line and the horizontal length of the word line is longer than a horizontal length of the bit line, and
wherein the source line, the word line, and the bit line face the same semiconductor pattern.

16. The semiconductor memory device of claim 15, wherein, in the extension region, a plurality of second vias electrically connect respective the source line, the word line, and the bit line to the second interconnection line, the second via electrically connected to the source line is longer than the second via electrically connected to the word line, and the second via electrically connected to the word line is longer than the second via electrically connected to the bit line.

17. The semiconductor memory device of claim 11, wherein the first interconnection line and the second interconnection line are not electrically connected to each other.

18. A semiconductor memory device comprising:
a semiconductor substrate;
a peripheral circuit structure disposed on the semiconductor substrate;
a volatile memory structure and a nonvolatile memory structure, disposed on the peripheral circuit structure,
wherein the volatile memory structure is a vertical dynamic random access memory (DRAM) and comprises:
a back gate structure having a cylindrical shape and extending in a vertical direction on the semiconductor substrate and including a back gate electrode layer and a back gate insulating layer surrounding the back gate electrode layer;
a plurality of semiconductor patterns, each having a ring-shaped horizontal section surrounding the back gate structure, and spaced apart from each other in the vertical direction;
a source line, a word line, and a bit line, which horizontally surround the semiconductor pattern and spaced apart from each other in the vertical direction; and
a front gate insulating layer disposed continuously between the semiconductor pattern and the word line, on an upper surface of the word line, and on a lower surface of the word line,
wherein the nonvolatile memory structure is a vertical NAND.

19. The semiconductor memory device of claim 18, further comprising a channel isolation insulating layer disposed between adjacent semiconductor patterns among the plurality of semiconductor patterns in the volatile memory structure,
wherein the channel isolation insulating layer comprises: a horizontal part having a first thickness in the vertical direction; and an edge part having a second thickness in the vertical direction greater than the first thickness,
wherein the plurality of semiconductor patterns are electrically separated from each other by the edge part of the channel isolation insulating layer.

20. The semiconductor memory device of claim 18, wherein the volatile memory structure is a capacitorless DRAM.
